(19) United States
(12) Patent Application Publication
(10) Pub. No.: US 2025/0318165 A1
(43) Pub. Date: Oct. 9, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Kaori FUSE, Nonoichi Ishikawa (JP); Keiko KAWAMURA, Yokohama Kanagawa (JP); Yoko IWAKAJI, Meguro Tokyo (JP); Takako MOTAI, Yokohama Kanagawa (JP); Hiroko ITOKAZU, Kawasaki Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/914,173

(22) Filed: Oct. 13, 2024

(30) Foreign Application Priority Data
Apr. 8, 2024 (JP) 2024-062174

(51) Int. Cl. H01L 29/739; H01L 27/07; H01L 29/06; H01L 29/36; H01L 29/861

(52) U.S. Cl. CPC H10D 12/441; H10D 8/00; H10D 62/102; H10D 62/60; H10D 84/811

(57) ABSTRACT

A semiconductor device of an embodiment includes a semiconductor substrate that includes a first principal surface and a second principal surface, the first principal surface and the second principal surface facing each other in a first direction, a drift region, a buffer region that includes a plurality of concentration peaks, a first electrode provided on the first principal surface, a second electrode provided on the second principal surface, and a transistor region, in which the plurality of concentration peaks includes a first concentration peak that is disposed closest to the second principal surface, a second concentration peak that is disposed farther from the second principal surface than the first concentration peak and has a higher impurity concentration than that of the first concentration peak, and a third concentration peak that is selectively providedbetween the first principal surface and the second concentration peak.

### CROSS-REFERENCE TO RELATED APPLICATION

This application is based upon and claims the benefit of priority from Japanese Patent Application No. 2024-062174, filed Apr. 8, 2024, the entire contents of which are incorporated herein by reference.

### FIELD

Embodiments of the present invention relate generally to a semiconductor device.

### BACKGROUND

Regarding a semiconductor element such as an insulated gate bipolar transistor (IGBT), a structure in which a buffer region with the impurity concentration higher than that of a drift layer is provided between the drift layer and a collector electrode has been known.

### DESCRIPTION OF THE DRAWINGS

FIG. 1 is a cross-sectional view of a semiconductor device 1 according to a first embodiment;

FIG. 2A is a diagram illustrating the impurity concentration distribution along line A-A′ illustrated in FIG. 1;

FIG. 2B is a diagram illustrating the impurity concentration distribution along line B-B′ illustrated in FIG. 1;

FIG. 3A is a diagram illustrating the carrier lifetime distribution along line A-A′ illustrated in FIG. 1;

FIG. 3B is a diagram illustrating the carrier lifetime distribution along line B-B′ illustrated in FIG. 1;

FIG. 4A is a cross-sectional view for explaining an operation when a semiconductor device is turned off;

FIG. 4B is a cross-sectional view for explaining an operation when the semiconductor device is turned off;

FIG. 4C is a cross-sectional view for explaining an operation when the semiconductor device is turned off;

FIG. 5A is a diagram illustrating the oscillation of a voltage waveform when the semiconductor device according to the first embodiment is turned off;

FIG. 5B is a diagram illustrating the oscillation of a voltage waveform when the semiconductor device according to the first embodiment is turned off;

FIG. 5C is a diagram illustrating the oscillation of a voltage waveform when the semiconductor device according to the first embodiment is turned off;

FIG. 6 is a diagram illustrating a relationship between the oscillation amplitude of a voltage waveform and a third carrier lifetime.

FIG. 7A is a diagram illustrating an impurity concentration distribution in a semiconductor device according to a first modification of the first embodiment;

FIG. 7B is a diagram illustrating an impurity concentration distribution in the semiconductor device according to the first modification of the first embodiment;

FIG. 8A is a diagram illustrating a carrier lifetime distribution in the semiconductor device according to the first modification of the first embodiment;

FIG. 8B is a diagram illustrating a carrier lifetime distribution in the semiconductor device according to the first modification of the first embodiment;

FIG. 9 is a cross-sectional view of a semiconductor device according to a second embodiment;

FIG. 10 is a diagram illustrating an impurity concentration distribution in the semiconductor device according to the second embodiment;

FIG. 11A is a top view of a semiconductor device according to a third embodiment;

FIG. 11B is a top view of the semiconductor device according to the third embodiment;

FIG. 12 is a top view of a semiconductor device according to a fourth embodiment; and

FIG. 13 is a top view of a semiconductor device according to a fifth embodiment.

### DETAILED DESCRIPTION

Hereinafter, each of embodiments of the present invention will be described with reference to the drawings.

A semiconductor device includes a semiconductor substrate that includes a first principal surface and a second principal surface, the first principal surface and the second principal surface facing each other in a first direction, a drift region that is provided in the semiconductor substrate, a buffer region that is provided between the first principal surface and the drift region and includes a plurality of concentration peaks having a higher impurity concentration than the drift region in the first direction, a first electrode that is provided on the first principal surface, a second electrode that is provided on the second principal surface, and a transistor region that includes a transistor provided with the first electrode serving as a collector electrode and the second electrode serving as an emitter electrode, in which the plurality of concentration peaks includes a first concentration peak that is disposed closest to the second principal surface, a second concentration peak that is disposed farther from the second principal surface than the first concentration peak and has a higher impurity concentration than an impurity concentration of the first concentration peak, and a third concentration peak that is selectively provided in a plane intersecting the first direction between the first principal surface and the second concentration peak.

Note that, the drawings are schematic or conceptual. The relationship between the thickness and the width of each portion, the ratio of the sizes between the portions, and the like are not necessarily the same as actual ones. In addition, even in the case of representing the same portion, dimensions and ratios may be represented differently from each other depending on the drawings.

For example, in the cross-sectional views in the present specification, laminated structures are illustrated, but the ratios of the thicknesses of individual layers in the laminated structures are not necessarily the same as an actual one. Even in a case where one layer is illustrated as being thicker than the other layer in the cross-sectional views, there may be a case where the thicknesses of the one layer and the other layer are substantially the same or a case where the one layer is thinner than the other layer in practice. That is, dimensions such as thicknesses illustrated in the drawings in the present specification may be different from actual dimensions.

In the following description, notations n⁺, n, and n⁻ and p⁺, p, and p⁻ represent relative high-low levels of impurity concentration in each conductivity-type. That is, n⁺ indicates that the n-type impurity concentration is relatively higher than n, and n-indicates that the n-type impurity concentration is relatively lower than n. In addition, p⁺ indicates that the p-type impurity concentration is relatively higher than p, and p⁻ indicates that the p-type impurity concentration is relatively lower than p. Note that n⁺-type and n⁻-type may be simply referred to as n-type, p⁺-type, and p⁻-type may be simply referred to as p-type.

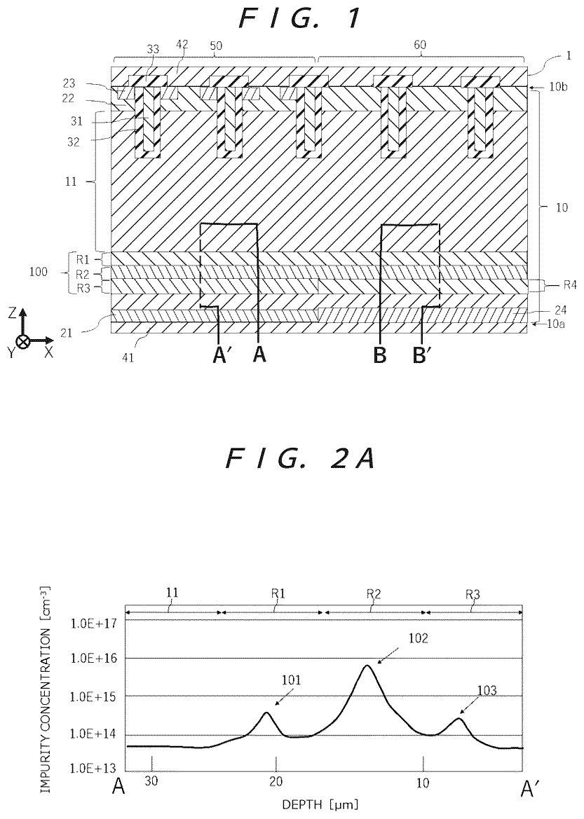

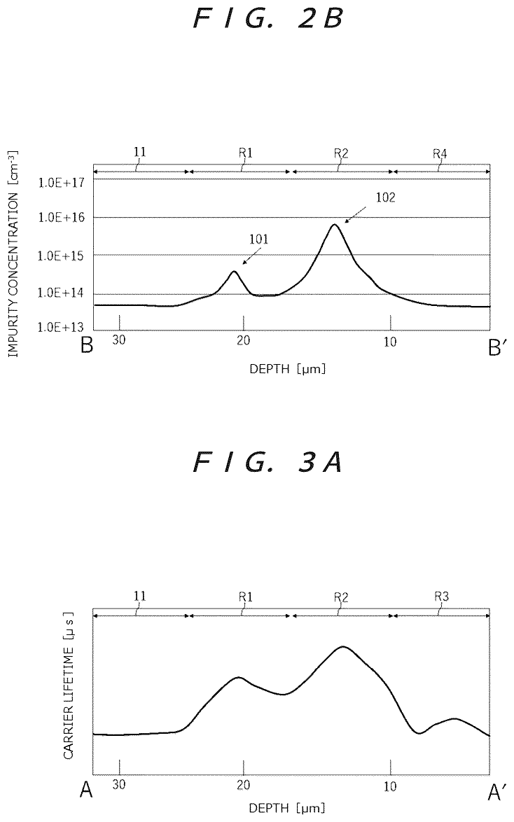

A direction from a first electrode 41 to a second electrode 42 is defined as a Z direction (first direction). A direction perpendicular to the Z direction is defined as an X direction (second direction), and a direction intersecting the X direction and the Z direction is defined as a Y direction (third direction). A semiconductor device 1 illustrated in FIG. 2 is illustrated in a cross-sectional view on an X-Z plane. Note that, the X direction, the Y direction, and the Z direction are illustrated in a perpendicular relationship in the present embodiment, but are not limited to the perpendicular relationship, and may be any relationship as long as they intersect each other. For the sake of explanation, the positive direction in the Z direction is referred to as “upper”. The negative direction in the Z direction is referred to as “lower”. However, the “upper” and “lower” directions are not limited to the gravity direction or the direction at the time of mounting the semiconductor device.

The length in the positive direction of the Z direction measured from a first principal surface 10a is defined as a depth. That is, the farther the position from the first principal surface 10a in the positive direction of the Z direction, the deeper the distance. In contrast, as the position is closer to the first principal surface 10a in the positive direction of the Z direction, it is described as shallow.

Note that, in the present specification and each drawing, the same elements as those described above with respect to the previously described drawings are denoted by the same reference numerals, and detailed description thereof will not be repeated.

### First Embodiment

FIG. 1 is a cross-sectional view of a semiconductor device 1 according to a first embodiment. FIG. 2A is a diagram illustrating the impurity concentration distribution along line A-A′ illustrated in FIG. 1. FIG. 2B is a diagram illustrating the impurity concentration distribution along line B-B′ illustrated in FIG. 1.

First, a cross-sectional view of the semiconductor device 1 will be described with reference to FIG. 1.

As illustrated in FIG. 1, the semiconductor substrate 10 includes a first principal surface 10a and a second principal surface 10b, which face each other in a Z direction. The semiconductor substrate 10 includes a drift region 11 with a first conductivity-type and a buffer region 100 with a first conductivity-type provided between the drift region 11 and the first principal surface 10a. The buffer region 100 includes regions R1, R2, R3, and R4. The regions R1 to R4 will be described later with reference to FIGS. 2 and 3.

The drift region 11 is, for example, an n-type drift region. The buffer region 100 is, for example, an n-type buffer region.

The first electrode 41 is provided beneath the first principal surface 10a. The second electrode 42 is provided on the second principal surface 10b facing the first principal surface 10a. The first electrode 41 and the second electrode 42 are formed of, for example, a metal containing Al.

The semiconductor device 1 has a transistor region 50 including a transistor and a diode region 60 including a diode. The transistor included in the transistor region 50 is provided with the first electrode 41 serving as a collector electrode and the second electrode 42 serving as an emitter electrode to control a current flowing between the first electrode 41 and the second electrode 42. The diode included in the diode region 60 is provided with the first electrode 41 serving as a cathode electrode and the second electrode 42 serving as an anode electrode and has a rectification effect to cause a current to flow from the second electrode 42 toward the first electrode 41. The transistor region 50 and the diode region 60 are provided adjacent to each other, for example. Hereinafter, an example of the semiconductor device 1 including a reverse conductive insulated gate bipolar transistor (RCIGBT) will be described.

First, the transistor region 50 will be described. In the transistor region 50, the buffer region 100 includes a first region R1, a second region R2, and a third region R3 in the descending order of depth. Furthermore, the transistor region 50 includes a first semiconductor region 21 with a second conductivity-type between the buffer region 100 and the first electrode 41.

The transistor region 50 also includes a second semiconductor region 22 with a second conductivity-type provided between the drift region 11 and the second electrode 42 and a third semiconductor region 23 with a first conductivity-type selectively provided on the second semiconductor region 22.

The gate insulating film 32 is provided in contact with the second semiconductor region 22 from the second principal surface 10b to a position reaching the drift region 11. The gate insulating film 32 surrounds the gate electrode 31. The gate electrode 31 and the second semiconductor region 22 are disposed opposite to each other with the gate insulating film 32 interposed therebetween. An interlayer insulating film 33 is provided between the gate electrode 31 and the second electrode 42. The gate electrode 31 and the second electrode 42 are electrically insulated by the interlayer insulating film 33.

In the transistor region 50, the first electrode 41 is, for example, a collector electrode, and the second electrode 42 is, for example, an emitter electrode. In addition, the first semiconductor region 21 is a p⁺-type collector region connected to a collector electrode, and the second semiconductor region 22 is a p-type base region, for example. The third semiconductor region 23 is an n⁺-type emitter region.

Next, the diode region 60 will be described. The diode region 60 functions as, for example, a free wheeling diode (FWD) with respect to the transistor region 50. The diode region 60 includes the drift region 11 and the buffer region 100. The buffer region 100 includes the first region R1, the second region R2, and a fourth region R4 in the descending order of depth. The impurity concentration distribution of the fourth region R4 is different from the impurity concentration distribution of the third region R3 of the transistor region 50.

In the diode region 60, a fourth semiconductor region 24 with the first conductivity-type is provided between the first electrode 41 and the buffer region 100. The fourth semiconductor region 24 is, for example, an n⁺-type cathode region.

The second semiconductor region 22 is provided on the drift region 11. The second semiconductor region 22 is, for example, a p-type anode region. The second semiconductor region 22 of the transistor region 50 and the second semiconductor region 22 of the diode region 60 may be formed by the same step. In addition, impurities may be further injected into the second semiconductor region 22 of the diode region 60 to achieve an impurity concentration higher than that of the second semiconductor region 22 of the transistor region 50.

Note that, FIG. 1 illustrates an example of the diode region 60 in which the third semiconductor region 23 is not formed, but in the diode region 60, the third semiconductor region 23 may also be formed to have the same structure as the transistor region 50.

In the diode region 60, the first electrode 41 is a cathode electrode of a diode, and the second electrode 42 is an anode electrode of the diode. Setting the second electrode 42 to a high potential with respect to the first electrode 41 enables a current to flow from the second electrode 42 to the first electrode 41.

Next, an operation of the semiconductor device 1 will be described.

First, a positive voltage is applied to the first electrode 41 with reference to the second electrode 42. Next, the voltage applied to the gate electrode 31 in the transistor region 50 is controlled. In a case where the voltage applied to the gate electrode 31 exceeds a threshold voltage, an inversion layer is generated in the second semiconductor region 22 near the gate insulating film 32.

Electrons can flow through the inversion layer from the second electrode 42 to the first electrode 41 in the transistor region 50, and the transistor region 50 is in an on-state. In a case where the transistor region 50 is being in the on-state, the first semiconductor region 21 is, for example, a p-type semiconductor region, and holes are injected from the first semiconductor region 21 into the drift region 11.

Subsequently, in a case where the voltage applied to the gate electrode 31 is controlled to be smaller than the threshold voltage, the inversion layer of the second semiconductor region 22 near the gate insulating film 32 is removed, and the transistor region 50 is in an off-state. That is, in the transistor region 50, the on- or off-state of the transistor formed in the transistor region 50 can be controlled by controlling the potential of the gate electrode 31.

Next, an operation of the diode region 60 will be described. When a positive voltage in a certain level or greater is applied to the second electrode 42 with respect to the first electrode 41, a current flows from the second electrode 42 to the first electrode 41, and the diode region 60 is in an on-state. Therefore, the diode region 60 can function as FWD that causes the current in the reverse direction generated in a case where an inductive load is connected to flow when the transistor region 50 is turned off or other state.

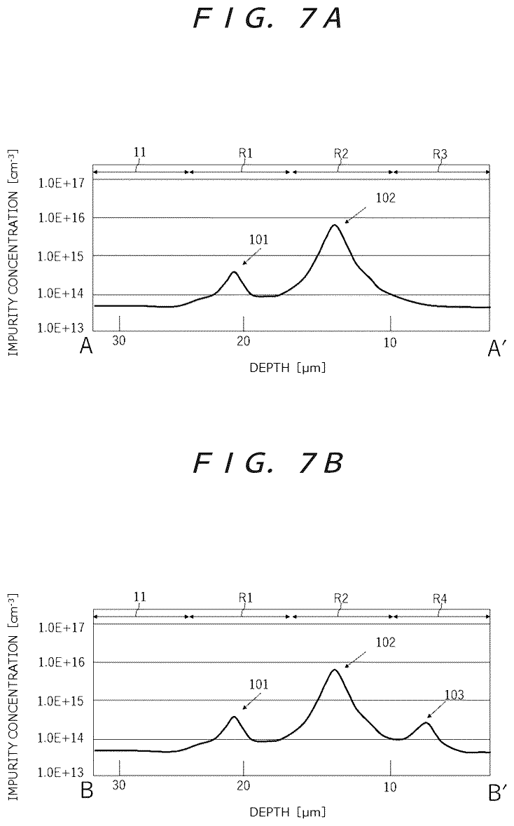

Subsequently, in a case where the potential of the second electrode 42 with respect to the first electrode 41 decreases in the diode region 60, the diode enters a recovery operation to transition into an off-state. Carriers remain in the semiconductor substrate 10 in the diode region 60 through which the current has flowed in the reverse direction, and a tail current associated with the discharge of the carriers flows during recovery. When the tail current has flowed, and the recovery operation has been then completed, the switching of the semiconductor device 1 is completed. The operation of the diode region 60 at the time of switching will be described later in detail with reference to FIG. 6 and FIGS. 7A and 7B.

As described above, a cross-sectional view of the semiconductor device 1 will be described with reference to FIG. 1.

Next, the structure of the buffer region 100 will be described with reference to FIGS. 2A and 2B. FIG. 2A is a diagram illustrating an example of the impurity concentration distribution along line A-A′ illustrated in FIG. 1. FIG. 2B is a diagram illustrating an example of the impurity concentration distribution along line B-B′ illustrated in FIG. 1. Here, the impurity concentration distributions are measured by, for example, the spreading resistance analysis (SRA). Furthermore, the concentration distribution may be smoothed by moving average or other method as necessary.

First, the impurity concentration distribution along line A-A′ will be described with reference to FIG. 2A. The line A-A′ longitudinally traverses the buffer region 100 formed in the transistor region 50 in the semiconductor substrate 10.

The horizontal axis in each of the graphs illustrated in FIGS. 2A and 2B is a distance (hereinafter, referred to as a depth) from the first principal surface 10a of the semiconductor substrate 10. The vertical axis represents the impurity concentration of the semiconductor substrate 10. Here, the impurity concentration indicated by the vertical axis represents the concentration of the carriers generated by activation of the injected impurities.

The impurity concentration distribution along the line A-A′ includes at least three concentration peaks of a first concentration peak 101, a second concentration peak 102, and a third concentration peak 103. The first region R1 of the buffer region 100 includes the first concentration peak 101. The second region R2 includes the second concentration peak 102. The third region R3 includes a third concentration peak 103. The third concentration peak 103 is provided in the transistor region 50 selectively among the transistor region 50 and the diode region 60.

Here, a peak of the impurity concentration distribution can be defined as the maximum value of the distribution obtained by smoothing the concentration distribution of the impurities injected and activated in the semiconductor substrate 10 in the Z direction which is a thickness direction of the semiconductor substrate 10. Here, the smoothing includes, for example, means for calculating a moving average or other method.

The drift region 11 is positioned at a position deeper than the buffer region 100. The drift region 11 has, for example, the flat impurity concentration distribution. Here, the fact that an impurity concentration is flat in a certain region can be defined by, for example, the minimum value and the maximum value of the impurity concentration distribution in the region. For example, provided that the maximum value of the impurity concentration after smoothing in a certain region is smaller than 1.5 times the minimum value, the region is defined as flat. Conversely, provided that the maximum value of the impurity concentration after smoothing in the certain region is 1.5 times or greater the minimum value, the region includes an impurity concentration peak.

The first concentration peak 101 is formed deeper than the second concentration peak 102. The second concentration peak 102 is formed deeper than the third concentration peak 103.

The first concentration peak 101 and the second concentration peak 102 are formed by, for example, protons and have an n-type conductivity. The first concentration peak 101 and the second concentration peak 102 are formed by, for example, an injection of impurities from the first principal surface 10a and performing annealing.

The annealing temperature for diffusing protons is, for example, 300° C. or higher and 500° C. or lower. The annealing temperature for diffusing protons is, for example, desirably 380° C. or higher and 400° C. or lower. The annealing is carried out as, for example, hydrogen plasma annealing.

For example, the first concentration peak 101 is formed at a depth of 10 μm or greater and 30 μm or smaller in the direction of the second principal surface 10b as measured from the first principal surface 10a. By setting the depth of the first concentration peak 101 to 10 μm or greater, the buffer region 100 controls the extension of a depletion layer to be slow down and minimizes the oscillation of a voltage waveform. In addition, by setting the depth of the first concentration peak 101 to 30 μm or smaller, the depletion layer easily expands in the semiconductor substrate 10, so that the withstand voltage can be maintained. Setting the depth of the first concentration peak 101 to 20 μm or smaller is desirable because the withstand voltage can be further improved. The depth of the first concentration peak 101 is desirably 10 μm or greater and 20 μm or smaller.

The impurity concentration of the first concentration peak 101 is smaller than the impurity concentration of the second concentration peak 102. The first concentration peak 101 and the second concentration peak 102 prevent the depletion layer from expanding in the direction from A to A′. Forming the impurity concentration of the first concentration peak 101 to be smaller than the impurity concentration of the second concentration peak 102 is desirable because the expansion of the depletion layer can be slow down, and the voltage waveform at the time of switching can be further stabilized.

In order to make the expansion of the depletion layer slow down and obtain the withstand voltage, the first concentration peak 101 has an impurity concentration of, for example, 1.0×10¹⁴ cm⁻³ or greater and 1.0×10¹⁵ cm⁻³ or smaller. The second concentration peak 102 has an impurity concentration of, for example, 1.0×10¹⁵ cm⁻³ or greater and 1.0×10¹⁷ cm⁻³ or smaller.

The third concentration peak 103 is formed by, for example, protons. The third concentration peak 103 has, for example, an n-type conductivity. The depth of the third concentration peak 103 is, for example, more than 0 μm and 10 μm or smaller.

The third concentration peak 103 has an impurity concentration lower than that of the second concentration peak 102, for example. It is desirable, in order to improve the efficiency of the impurity injection, that the third concentration peak has a lower impurity concentration, and the injection amount of the impurities for forming the third concentration peak 103 is smaller.

As described above, the impurity concentration distribution along line A-A′ in FIG. 1 has been described with reference to FIG. 2A. Next, the impurity concentration distribution along line B-B′ in FIG. 1 will be described with reference to FIG. 2B.

FIG. 2B is a diagram illustrating the impurity concentration distribution along line B-B′ illustrated in FIG. 1. The line B-B′ longitudinally traverses the buffer region 100 in the diode region 60 in the Z direction. At least a first concentration peak 101 and a second concentration peak 102 are generated along the line B-B′. The first concentration peak 101 is formed at a position deeper than the second concentration peak 102.

The first region R1 in the diode region 60 includes the first concentration peak 101. The second region R2 includes the second concentration peak 102. The impurity concentration distributions of the first region R1 and the second region R2 may be, for example, the same as the impurity concentration distributions of the first region R1 and the second region R2 of the transistor region 50 illustrated in FIG. 2A.

The fourth region R4 has, for example, the flat impurity concentration distribution.

The first concentration peak 101 illustrated in FIG. 2B is formed by, for example, the same step as the first concentration peak 101 illustrated in FIG. 2A. The second concentration peak 102 illustrated in FIG. 2B is formed by, for example, the same step as the second concentration peak 102 illustrated in FIG. 2A. Forming at least a part of the buffer regions of the transistor region 50 and the diode region 60 in the same step is desirable because the manufacturing efficiency is improved.

Next, the distribution of the carrier lifetime will be described with reference to FIGS. 3A and 3B. Hereinafter, the carrier lifetime is measured by, for example, a μ-photo conductive decay (PCD) method. However, it is not necessary to acquire the continuous profile illustrated in FIGS. 3A and 3B, and the carrier lifetime may be measured and compared discretely in the depth direction. FIG. 3A is a schematic diagram illustrating the carrier lifetime distribution along line A-A′ illustrated in FIG. 1. FIG. 3B is a schematic diagram illustrating the distribution of the carrier lifetime along line B-B′ illustrated in FIG. 1.

In the semiconductor substrate 10, first, the entire surface is irradiated with an electron beam to form crystal defects in the first region R1, the second region R2, the third region R3, the fourth region R4, and the drift region 11, for example. Since the generated crystal defects promote carrier recombination, carrier lifetime is uniformly reduced. The formed crystal defects can be repaired by, for example, protons. Next, for example, protons are injected to recover the crystal defects and locally recover the carrier lifetime.

That is, after the control to reduce the carrier lifetime in the first region R1, the second region R2, the third region R3, and the fourth region R4 is performed by the electron beam irradiation, impurities, for example, such as protons are injected to recover the carrier lifetime, and as a result, the lifetime distribution illustrated in FIGS. 3A and 3B can be obtained.

First, FIG. 3A will be described. In the distribution of the carrier lifetime illustrated in FIG. 3A, for example, the carrier lifetime is recovered at positions corresponding to the first concentration peak 101, the second concentration peak 102, and the third concentration peak 103 formed by injecting protons.

A representative value of the carrier lifetime in the first region R1 is referred to as a first carrier lifetime LT1. A representative value of the carrier lifetime in the second region R2 is referred to as a second carrier lifetime LT2. A representative value of the carrier lifetime in the third region R3 is referred to as a third carrier lifetime LT3. The representative value may be defined as, for example, an average value of the carrier lifetime in each region. Here, the average value is an average of the carrier lifetime measured at two or more points in each region. Note that, the carrier lifetime measured at one point in each region may be used as the representative value. The same applies to a fourth carrier lifetime LT4 to be described later.

The second carrier lifetime LT2 is greater than the first carrier lifetime LT1 and the third carrier lifetime LT3. The first carrier lifetime LT1 and the second carrier lifetime LT2 are greater than the carrier lifetime in the drift region 11.

Next, the schematic diagram illustrating the distribution of the carrier lifetime along line B-B′ in FIG. 1 will be described with reference to FIG. 3B. FIG. 3B illustrates the drift region 11, the first region R1, the second region R2, and the fourth region R4.

In FIG. 3B, a representative value of the carrier lifetime in the fourth region R4 is referred to as a fourth carrier lifetime LT4. The fourth carrier lifetime LT4 is smaller than the first carrier lifetime LT1 in the first region R1 and the second carrier lifetime LT2 in the second region R2. The fourth carrier lifetime LT4 is smaller than the carrier lifetime in the drift region 11.

In a case where impurities are injected from the first principal surface 10a in order to form the second concentration peak 102 illustrated in FIGS. 2A and 2B, defects occur in the crystal lattice due to the passing impurities at a position closer to the first principal surface 10a than the second concentration peak 102. Since the generated crystal defects promote carrier recombination, the carrier lifetime is reduced in the region where the impurities have passed.

The impurities injected from the first principal surface 10a pass through the fourth region R4 to form the first concentration peak 101 and the second concentration peak 102. As the impurities pass through the fourth region R4, the crystal defects occur in the fourth region R4, and the fourth carrier lifetime LT4 decreases. On the other hand, in the third region R3 illustrated in FIG. 3A, the carrier lifetime is recovered along with the formation of the third concentration peak 103. Therefore, the crystal defects are not repaired in the fourth region R4 illustrated in FIG. 3B, and the fourth carrier lifetime LT4 shorter than the third carrier lifetime LT3 in the third region R3 illustrated in FIG. 3A is obtained.

The carrier lifetime distributions of the first region R1 and the second region R2 in the diode region 60 may be, for example, the same as the carrier lifetime distributions of the first region R1 and the second region R2 in the transistor region 50 illustrated in FIG. 3A. The third concentration peak 103 is selectively provided in the XY plane between the first principal surface 10a of the semiconductor substrate 10 and the second concentration peak 102 of the buffer region 100. That is, a portion having the third concentration peak 103 (for example, the third region R3) and a portion having no third concentration peak 103 (for example, the fourth region R4) are provided in the XY plane. As described above, the impurity concentration distribution and the carrier lifetime distribution have been described with reference to FIGS. 2A and 2B, and 3A and 3B.

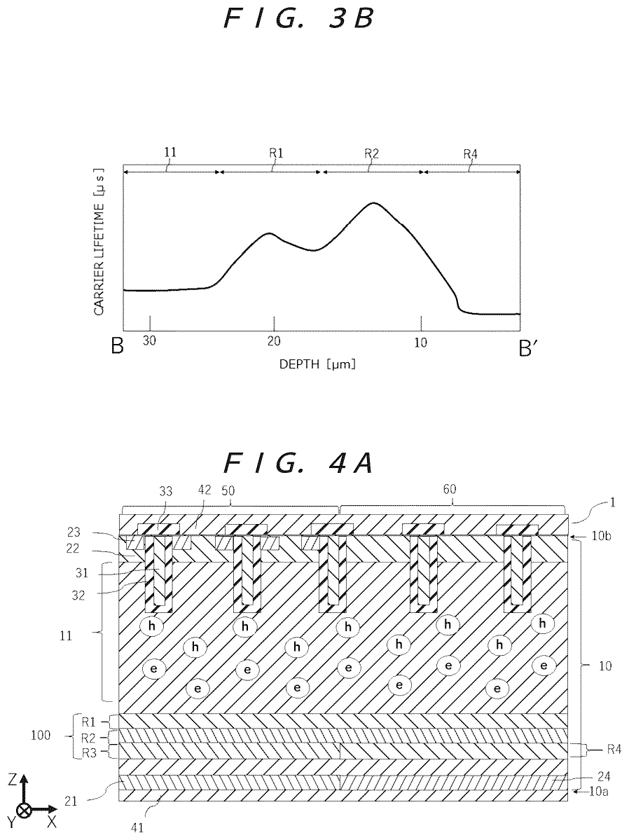

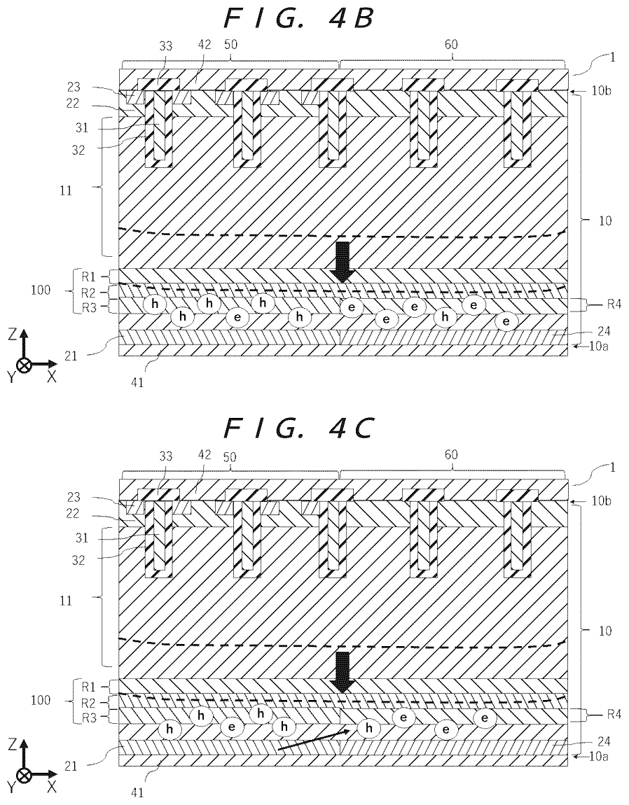

Next, with reference to FIGS. 4A, 4B, and 4C, the operation of the semiconductor device 1 at the time of switching will be described in detail in association with the carrier lifetime distribution. FIGS. 4A, 4B, and 4C are cross-sectional views illustrating the behavior of carriers when the transistor region 50 is turned off. FIG. 4A is a schematic diagram illustrating carriers (electrons e and holes h) remaining in the drift region 11. FIG. 4B is a schematic diagram illustrating that a depletion layer is expanding, which is indicated by dotted line. FIG. 4C is a schematic diagram illustrating that a hole is injected into the diode region 60 from the first semiconductor region 21 while remaining carriers are removed.

When the semiconductor device 1 is switched, for example, when the transistor region 50 is turned off, electrons and holes remain in the drift region 11 as illustrated in FIG. 4A. The electrons and holes remaining in the drift region 11 are carriers responsible for a current of the transistor region 50 or the diode region 60. In order to complete the turn-off operation of the semiconductor device 1 (including the recovery operation of the diode region 60), it is necessary that electrons and holes are discharged from the first electrode 41 or the second electrode 42, or electrons and holes are removed by recombination.

As the carriers are removed from the drift region 11, the depletion layer expands in the direction indicated by the arrow in FIG. 4B. The depletion layer expands in the drift region 11 in the direction from the second principal surface 10b to the first principal surface 10a. In a case where the carriers are discharged from the drift region 11, the depletion layer reaches the buffer region 100.

The buffer region 100 has an impurity concentration higher than that of the drift region 11 in at least a part thereof. Therefore, in a case where the depletion layer reaches the buffer region 100, the expansion of the depletion layer is slow down.

It is desirable to cause the impurity concentration of the first concentration peak 101 illustrated FIGS. 2A and 2B to be smaller than the impurity concentration of the second concentration peak 102 because the expansion of the depletion layer toward the first principal surface 10a can be slow down. Here, making the expansion of the depletion layer slow down means to control the expansion of the depletion layer stepwise by increasing the impurity concentration stepwise from the second principal surface 10b toward the first principal surface 10a.

When the depletion layer reaches the buffer region 100, carriers remaining between the depletion layer and the first principal surface 10a are referred to as remaining carriers. The current flowing by the discharged remaining carriers is referred to as a tail current.

The shorter the carrier lifetime of the remaining carriers, the shorter the time for the remaining carriers to be recombined. That is, it is possible that the time during which the tail current flows is shortened, and the switching loss is reduced. On the other hand, as the carrier lifetime of the remaining carriers is shorter, the remaining carriers are more rapidly recombined, resulting in the rapid expansion of the depletion layer in the direction of the first principal surface 10a. Therefore, the voltage waveform at the time of switching may be unstable to promote the oscillation of the voltage.

On the other hand, as the carrier lifetime of the remaining carriers is longer, the remaining carriers are more slowly recombined. Since the remaining carriers are slowly recombined, the tail current flows for a longer time than in the case where the carrier lifetime is short, but rapid carrier recombination does not occur.

In the transistor region 50 illustrated in FIGS. 4A, 4B, and 4C, the lifetime is recovered in the third region R3 of the buffer region 100 (see FIG. 3A). Therefore, between FIGS. 4B and 4C, recombination of the remaining carriers in the transistor region 50 progresses more slowly in the third region R3 than in the fourth region R4, for example.

The remaining carriers illustrated in the diode region 60 are gradually removed by recombination or the like from FIGS. 4B to 4C. In the fourth region R4, as illustrated in FIG. 3B, the carrier lifetime is not recovered, and the removal of the carriers rapidly proceeds as compared with, for example, the third region R3.

On the other hand, as illustrated in FIG. 4C, the hole is injected from the first semiconductor region 21 (p-type) in the transistor region 50 adjacent to the diode region 60 to compensate for the reduced remaining carriers due to the recombination. Here, the hole injection is promoted as the n-type impurity concentration of the third region R3 is smaller. This is because recombination of holes, flowing to the diode region 60 through the third region R3, and electrons in the third region R3 is prevented.

That is, although the fourth carrier lifetime LT4 in the diode region 60 is shorter than the third carrier lifetime LT3 in the transistor region 50, the injection of the carriers from the first semiconductor region 21 prevents the rapid removal of the remaining carriers in the diode region 60.

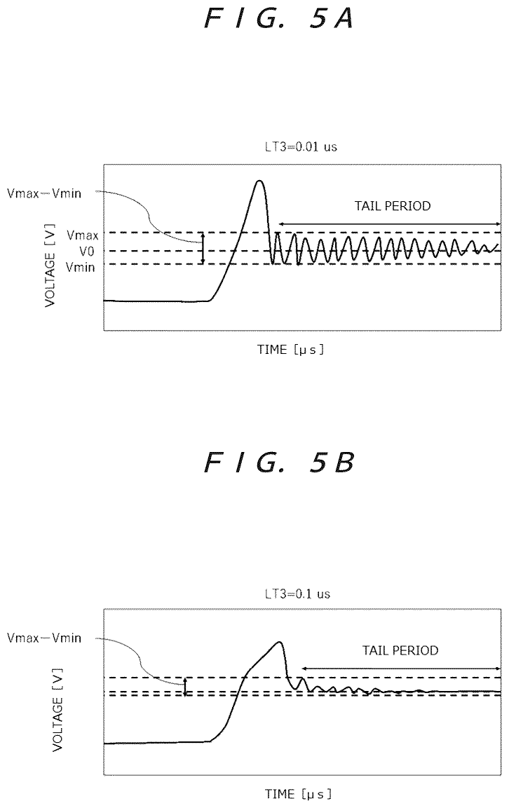

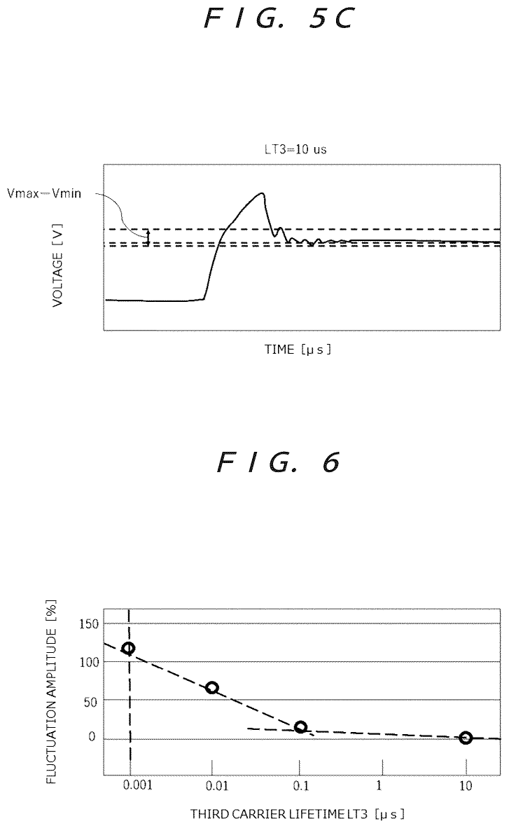

Next, the relationship between the carrier lifetime and the oscillation amplitude of the voltage waveform will be described with reference to FIGS. 5A, 5B, and 5C, and FIG. 6. FIGS. 5A, 5B, and 5C illustrate voltage waveforms obtained by the simulation in a case where the third carrier lifetime LT3 is 0.01 μs, 0.1 μs, and 10 μs. The horizontal axis represents time. The vertical axis represents a potential difference between the first electrode 41 and the second electrode 42. The vertical axis represents, for example, a collector-emitter voltage in the IGBT.

First, FIG. 5A illustrates a case of LT3=0.01 μs. A state in which the voltage converges to V0 after switching is illustrated. Here, V0 is a power supply voltage, for example, 600 V. The discharge of the remaining carriers continues in a tail period in which the tail current flows, and the voltage waveform fluctuates. In a case of focusing on the behavior of the tail current associated with the remaining carrier, the voltage waveform in the tail period is used for evaluation of the oscillation amplitude.

The magnitude of the oscillation amplitude is evaluated based on the vibration of the voltage waveform as follows. It is defined that as the value obtained by dividing the difference between the maximum value and the minimum value of the voltage waveform fluctuating in the tail period by the power supply voltage, that is, the value (Vmax−Vmin)/V0 obtained by subtracting the minimum value Vmin from the maximum value Vmax and dividing the resulting value by V0 in FIG. 5A is large, the oscillation amplitude of the voltage waveform is large. It means, hereinafter, that in a case where the oscillation amplitude is large, (Vmax−Vmin)/V0 is large for the voltage waveform in the tail period.

FIG. 5B illustrates a case of LT3=0.1 μs. That is, it is illustrated that the recovery amount of the carrier lifetime in the third region R3 is greater than that in the case illustrated in FIG. 5A. In FIG. 5B, the value of Vmax−Vmin is smaller than that illustrated in FIG. 5A, and the oscillation amplitude of the voltage waveform illustrated in FIG. 5B is smaller than the oscillation amplitude of the voltage waveform illustrated in FIG. 5A. That is, the case of LT3=0.1 us can further suppress the vibration of the voltage in the tail period as compared to the case of LT3=0.01 μs.

FIG. 5C illustrates a voltage waveform when LT3 is further increased to be LT3=10 μs. The oscillation amplitude of the voltage waveform in FIG. 5C is smaller than the oscillation amplitude of the voltage waveform in FIG. 5A. On the other hand, the difference between the oscillation amplitudes in FIGS. 5B and 5C is not significant as compared with the difference between the oscillation amplitudes in FIGS. 5A and 5B.

The relationship between the third carrier lifetime LT3 and the oscillation amplitude in FIGS. 5A, 5B, and 5C described above is summarized in FIG. 6. FIG. 6 also includes a result of LT3=0.001 μs, which is not illustrated in FIG. 5. The horizontal axis represents the first carrier lifetime LT1 in the log scale, and the vertical axis represents the oscillation amplitude in percentage.

As illustrated in FIG. 6, the oscillation amplitude decreases as the third carrier lifetime LT3 increases. That is, as impurities such as protons are injected into the third region R3 to recover crystal defects, the oscillation amplitude can be reduced.

The carrier lifetime before the third carrier lifetime LT3 is recovered in the third region R3 is, for example, smaller than 0.001 μs. The fourth carrier lifetime LT4 in the fourth region R4 of the diode region 60 is, for example, smaller than 0.001 μs. That is, the oscillation amplitude in a case where the carrier lifetime recovery is not performed is greater than 120%.

By controlling to recover the third carrier lifetime LT3 to 0.001 μs or greater, the oscillation amplitude can be reduced to 120% or smaller.

Furthermore, by setting the third carrier lifetime LT3 to 0.01 μs or greater, the oscillation amplitude can be reduced to 60%.

In the range of LT3<0.1 μs and the range of LT3≥0.1 μs, the slope of the approximate straight line illustrated in FIG. 6, that is, the reduction rate of the oscillation amplitude varies. In the range of LT3<0.1 μs, the reduction rate of the oscillation amplitude is greater than that in the range of LT3≥0.1 μs. In the range of LT3≥0.1 μs, the reduction in the oscillation amplitude approaches a saturation level. By setting LT3 to 0.1 μs or greater, the reduction in the oscillation amplitude reaches the saturation level, and the oscillation amplitude can be sufficiently reduced. In addition, in the case of LT3≥1 μs, the oscillation amplitude can be further reduced.

Note that, the third carrier lifetime LT3 is, for example, 100 μs or smaller in consideration of not increasing the switching loss. Furthermore, LT3≤50 μs may be adopted, and LT3≤10 μs may be adopted.

In order to reduce the oscillation amplitude, the third carrier lifetime LT3 is, for example, 0.001 μs≤LT3≤100 μs. Desirably, 0.1 μs≤LT3≤10 μs.

Note that, the carrier lifetime in the drift region 11 is typically several tens of μs, for example, about 10 μs. Here, the carrier lifetime in the drift region 11 is, for example, an average calculated in the region. The third carrier lifetime LT3 is, for example, 1/1000 times or greater of the carrier lifetime in the drift region 11. It is desirably 1/100 times or greater of the carrier lifetime in the drift region 11. It is further desirably 1/10 times or greater of the carrier lifetime in the drift region 11.

In addition, the crystal defects are removed by impurities included in the third concentration peak 103 illustrated in FIG. 2A to cause the third carrier lifetime LT3 to be recovered. Here, the total injection amount Tin of the third concentration peak 103 is defined as follows. The impurity concentration values based on the flat impurity concentration of the drift region 11 among the impurity concentration distributions are integrated from the depth corresponding to the minimum between the second concentration peak 102 and the third concentration peak 103 to the first principal surface 10a. The concentration per unit area on the XY plane obtained by the integration is regarded as the amount of impurities injected to form the third concentration peak 103, and is defined as the total injection amount Tin.

In order to recover the third carrier lifetime LT3 and reduce the oscillation amplitude, for example, the total injection amount Tin is 1×10¹¹ cm⁻² or greater and 1×10¹⁶ cm⁻² or smaller. It is possible to sufficiently recover the lifetime by the injection of the impurities of 1×10¹¹ cm⁻² or greater per unit area. In addition, the damage to a wafer is prevented by reducing the amount of impurities to 1×10¹⁶ cm⁻² or smaller per unit area. In order to satisfy LT3≥0.1 μs, the total injection amount Tin is desirably 8×10¹¹ cm⁻² or greater and 1×10¹⁶ cm⁻² or smaller. In order to further reduce the damage to the wafer, the total injection amount Tin is desirably 1×10¹⁴ cm⁻² or smaller.

In a case where the impurity concentration is expanded with respect to the third concentration peak 103 within a position from a depth of approximately 0 μm to −10 μm, the total injection amount Tin is 1×10¹¹ cm⁻² or greater. Therefore, even though the flat concentration distribution is assumed from a depth of 0 μm to −10 μm, the impurity concentration is 1×10¹⁴ cm⁻³. Since the third concentration peak 103 has a higher impurity concentration than the surroundings, the impurity concentration of the third concentration peak 103 is 1×10¹⁴ cm⁻³ or greater. In order to recover the lifetime, the impurity concentration of the third concentration peak 103 is desirably 8×10¹⁴ cm⁻³ or greater.

The impurity concentration of the third concentration peak 103 is smaller than the impurity concentration of the second concentration peak 102. In order to prevent the damage to the wafer, for example, the total injection amount Tin is 1×10¹⁴ cm⁻² or smaller, and the impurity concentration of the third concentration peak 103 is 1×10¹⁷ cm⁻³ or smaller. In a case where the third concentration peak 103 has an amount of impurities sufficient to recover the third carrier lifetime LT3, a smaller impurity concentration is desirable to prevent the damage to the wafer.

The semiconductor device 1 according to the present embodiment includes the buffer region 100 having various impurity concentration distributions in the transistor region 50 and the diode region 60. The third carrier lifetime LT3 is greater than the fourth carrier lifetime LT4. Suppressing the rapid removal of the carriers can cause the reduction of the oscillation amplitude of the voltage waveform at the time of switching. In a case where the third carrier lifetime LT3 is, for example, 0.01 μs≤LT3≤100 μs, the oscillation amplitude can be further reduced.

The reduction of the oscillation amplitude and the reduction of the switching loss are generally in a trade-off relationship with respect to the length of the carrier lifetime. In a case where the buffer region 100 is common to the transistor region 50 and the diode region 60, it is necessary to prioritize one of the reduction of the oscillation amplitude and the reduction of the switching loss over the other. For example, in a case where the lifetime recovery is uniformly performed in both the transistor region and the diode region, the switching time may be longer, resulting that the switching loss may increase.

According to the semiconductor device 1 of the present embodiment, it is possible to improve the trade-off between the reduction of the oscillation amplitude and the reduction of the switching loss by giving priority to the reduction of the oscillation amplitude in a part of the semiconductor device and giving priority to the reduction of the switching loss in another part of the semiconductor device.

In the transistor region 50, since the carrier lifetime is recovered in the third region R3, the oscillation of the voltage waveform can be minimized. The fourth carrier lifetime LT4 of the fourth region R4 in the diode region 60 is smaller than the third carrier lifetime LT3 of the transistor region 50 and promotes carrier recombination in the diode region 60. As a result, the switching time is shortened, and the switching loss is reduced. On the other hand, in a case where the transistor region 50 and the diode region 60 are adjacent to each other, it is possible to minimize the oscillation of the voltage waveform by the injection of holes from the transistor region 50 to the diode region 60. Therefore, the switching loss can be reduced, and the oscillation amplitude can be reduced.

In a case where different buffer regions 100 are provided for the transistor region 50 and the diode region 60, it is desirable to manufacture a common structure in the same step from the viewpoint of manufacturing efficiency. According to the present embodiment illustrated in FIG. 1, in the buffer region 100, by applying a common structure to the first region R1 and the second region R2, the transistor region 50 and the diode region 60 can be formed in the same step.

The first semiconductor region 21 and the fourth semiconductor region 24 may have different conductivity types and impurity concentrations from each other. In order to form the first semiconductor region 21, it is required to apply a mask to the diode region 60 and inject impurities into the transistor region 50. The third region R3 can be selectively formed in the transistor region 50 in the XY plane by using the mask provided in a step of applying the mask to the diode region 60 to form the first semiconductor region 21.

Furthermore, the second concentration peak 102 has an impurity concentration of, for example, 1.0×10¹⁵ cm⁻³ or greater and 1.0×10¹⁷ cm⁻³ or smaller, and has an impurity concentration greater than those of the first concentration peak 101 and the third concentration peak 103. The switching operation can be further stabilized by causing the extension of the depletion layer at the time of switching to be stopped at the second region R2 with the second concentration peak 102.

### Modification of First Embodiment

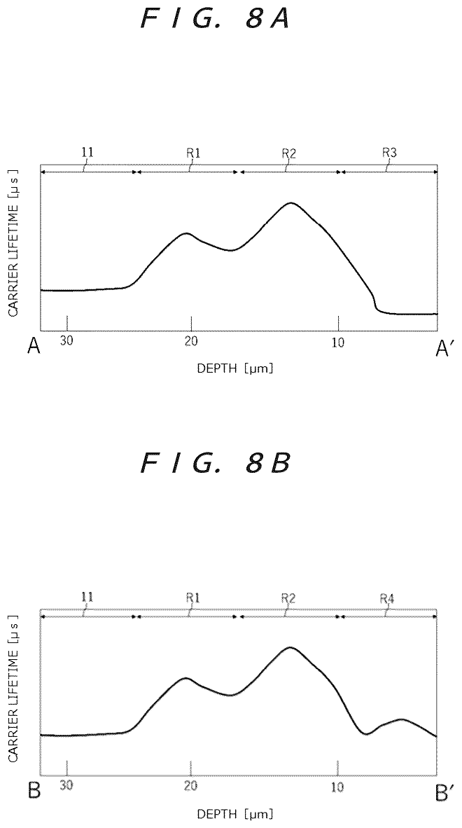

Next, a modification of the first embodiment will be described with reference to FIGS. 7A and 7B, and FIGS. 8A and 8B. FIG. 7A illustrates the impurity concentration distribution along line A-A′ illustrated in FIG. 1. FIG. 7B illustrates the impurity concentration distribution along line B-B′ illustrated in FIG. 1. FIG. 8A illustrates the carrier lifetime distribution along line A-A′ illustrated in FIG. 1. FIG. 8B illustrates the carrier lifetime distribution along line B-B′ illustrated in FIG. 1. Some redundant descriptions common to the first embodiment will not be repeated.

In the first embodiment, the control to selectively recover the lifetime is performed in the third region R3 of the transistor region 50, whereas in the present modification, the control to selectively recover the lifetime is performed in the fourth region R4 of the diode region 60. In other words, the third concentration peak 103 is provided in the diode region 60 selectively among the transistor region 50 and the diode region 60.

First, the impurity concentration distribution of the present modification along line A-A′ in the transistor region 50 illustrated in FIG. 1 will be described with reference to FIG. 7A. The first region R1 includes the first concentration peak 101. The second region R2 includes the second concentration peak 102. The third region R3 has, for example, the flat impurity concentration distribution. The impurity concentration distribution along line A-A′ in the present modification is, for example, the same as the impurity concentration distribution illustrated in FIG. 2B.

Next, the impurity concentration distribution of the present modification along line B-B′ in the diode region 60 illustrated in FIG. 1 will be described with reference to FIG. 7B. The first region R1 includes the first concentration peak 101. The second region R2 includes the second concentration peak 102. The fourth region R4 includes the third concentration peak 103.

In the present modification, at the depth at which the third concentration peak 103 is formed in the fourth region R4, the impurity concentration of the fourth region R4 in the diode region 60 is greater than the impurity concentration of the third region R3 in the transistor region 50.

Next, the carrier lifetime distribution of the present modification along line A-A′ in the transistor region 50 illustrated in FIG. 1 will be described with reference to FIG. 8A. The first carrier lifetime LT1 in the first region R1 and the second carrier lifetime LT2 in the second region R2 is greater than the third carrier lifetime LT3 in the third region R3. The third carrier lifetime LT3 is smaller than the carrier lifetime in the drift region 11. The carrier lifetime distribution along line A-A′ in the present modification may be, for example, the same as the distribution illustrated in FIG. 3B.

The carrier lifetime distribution of the present modification along line B-B′ in the diode region 60 illustrated in FIG. 1 will be described with reference to FIG. 8B. The fourth carrier lifetime LT4 in the fourth region R4 in FIG. 8B is greater than the third carrier lifetime LT3 in the third region R3 in FIG. 8A. The carrier lifetime distribution along line B-B′ in the present modification may be, for example, the same as the distribution illustrated in FIG. 3A.

According to the present modification, by recovering the fourth carrier lifetime LT4 in the diode region 60, the oscillation amplitude at the time of recovery in the diode region 60 can be further reduced.

As the fourth carrier lifetime LT4 is longer, the removal of the remaining carriers at the time of the recovery operation is slow down. In the diode region 60, although the rapid removal of the carriers is prevented by the injection of the carriers from the first semiconductor region 21 of the transistor region 50, but in the present modification, the removal of the carriers is further slow down by the control of the carrier lifetime in the fourth region R4.

The fourth carrier lifetime LT4 is, for example, 0.001 μs≤LT4≤100 μs. 0.01 μs≤LT4≤10 μs may be adopted. 1 μs≤LT4≤10 μs may be adopted.

In addition, since the recovery process of the lifetime is not performed in the transistor region 50, the crystal defects generated in the third region R3 when the second concentration peak 102 and the third concentration peak 103 are formed is not recovered. Thus, the third carrier lifetime LT3 is smaller than the carrier lifetime of the drift region 11. Since the third carrier lifetime LT3 is short, the switching time is shortened in the transistor region 50. Therefore, the switching loss can be reduced.

Furthermore, the impurity concentration of the third region R3 in the transistor region 50 is approximately the same as the impurity concentration in the drift region 11. Thus, the injection of the holes from the transistor region 50 to the diode region 60 at the time of switching is promoted as compared with a case where an impurity concentration peak with a size of 1.0×10¹⁴ cm⁻³ or greater is formed in the third region R3, for example. It is possible to further prevent the rapid removal of the carriers in the diode region 60 and to reduce the oscillation amplitude.

According to the present modification, it is possible to improve the trade-off between the reduction of the oscillation amplitude and the reduction of the switching loss.

In a step of injecting the impurities into the fourth region R4, the injection of the impurities is required to be selectively performed in the diode region 60 in the XY plane, and can be performed with a mask in a step of forming the fourth semiconductor region 24. That is, the manufacturing step can be shortened as compared with a case where a new mask step is provided to form the buffer region 100.

Although the RCIGBT has been described as an example in the first embodiment, it is sufficient that the semiconductor device has at least the transistor region 50. In this case, by the selective formation of the third concentration peak 103 in the transistor region 50 in the XY plane, the oscillation of the voltage can be minimized at the time of switching while reducing the switching loss. This is because, the switching speed is improved, and the switching loss is reduced by providing a wide region having a small lifetime as compared with the case where the third concentration peak 103 is formed on the entire surface of the transistor region 50. On the other hand, as compared with the case where the third concentration peak 103 does not exist in the transistor region 50, the carriers are slowly removed to minimize the oscillation amplitude of the voltage waveform. By the selective recovery of the lifetime in the transistor region 50 in the XY plane, it is possible to improve the trade-off between the reduction of the oscillation amplitude and the reduction of the switching loss.

### Second Embodiment

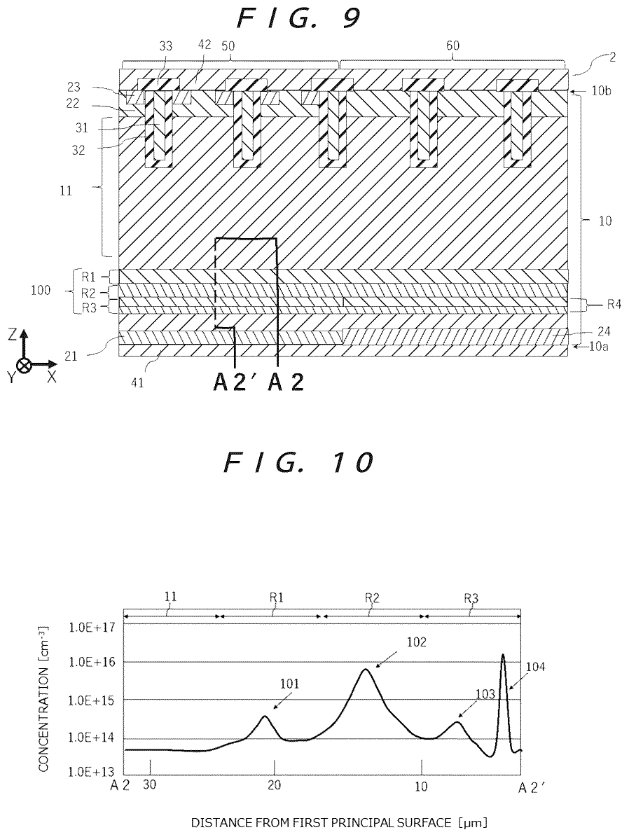

Subsequently, a semiconductor device 2 according to a second embodiment will be described with reference to FIG. 9. Some redundant descriptions of the components common to the semiconductor device 1 according to the first embodiment will not be repeated. FIG. 9 is a cross-sectional view of a semiconductor device 2 according to the second embodiment. The difference from the cross-sectional view illustrated in FIG. 1 is the structures of the third region R3 and the fourth region R4 in the buffer region 100.

FIG. 10 is a diagram illustrating the impurity concentration distribution along line A2-A2′ illustrated in FIG. 9. The impurity concentration distribution illustrated in FIG. 10 includes a first concentration peak 101, a second concentration peak 102, a third concentration peak 103, and a fourth concentration peak 104 in the descending order of depth.

The third region R3 includes at least two concentration peaks including the third concentration peak 103 and the fourth concentration peak 104.

The first concentration peak 101, the second concentration peak 102, and the third concentration peak 103 are formed by, for example, injecting protons. The fourth concentration peak 104 is formed by, for example, injecting P (phosphorus).

The fourth concentration peak 104 is, for example, formed at a position of a depth of greater than 0 μm and 10 μm or smaller from the first principal surface 10a. The depth of the fourth concentration peak 104 is equal to or shallower than the depth of the third concentration peak 103.

The fourth concentration peak 104 has an impurity concentration of, for example, 1.0×10¹⁵ cm⁻³ or greater and 1.0×10¹⁷ cm⁻³ or smaller. The impurity concentration of the fourth concentration peak 104 is greater than the impurity concentration of the third concentration peak 103.

The first concentration peak 101 has an impurity concentration of, for example, 1.0×10¹³ cm⁻³ or greater and 1.0×10¹⁵ cm⁻³ or smaller. The second concentration peak 102 has an impurity concentration of, for example, 1.0×10¹⁴ cm⁻³ or greater and 1.0×10¹⁶ cm⁻³ or smaller. The third concentration peak 103 has an impurity concentration of, for example, 1.0×10¹³ cm⁻³ or greater and 1.0×10¹⁵ cm⁻³ or smaller.

It is desirable to form the fourth concentration peak 104 commonly in the fourth region R4 of the diode region 60 in that the manufacturing efficiency is improved.

Although the example in which the third concentration peak 103 is formed in the transistor region 50 is illustrated in FIG. 10, the third concentration peak 103 and the fourth concentration peak 104 may be formed in the diode region 60 as in the first modification of the first embodiment.

According to the semiconductor device 2 of the present embodiment, since the buffer region 100 includes the fourth concentration peak 104, the depletion layer can be prevented from reaching the first principal surface 10a. Since the extension of the depletion layer is stopped at a position not exceeding the fourth concentration peak 104, the voltage waveform at the time of switching of the semiconductor device 2 can be stabilized, and the switching characteristics can be improved.

Since the extension of the depletion layer can be more reliably stopped by the fourth concentration peak 104, the impurity concentrations of the first concentration peak 101 and the second concentration peak 102 can be made smaller than those of the semiconductor device 1 according to the first embodiment. Therefore, the injection amount of impurities such as protons required to form the first concentration peak 101 and the second concentration peak 102 can be reduced. That is, the efficiency of impurity injection can be improved.

The fourth concentration peak 104 can be a buffer containing P (phosphorus). Generally, a buffer containing P (phosphorus) may require annealing at a high temperature equal to or higher than the melting point of Al for diffusion of P (phosphorus). The structure on the first principal surface 10a side may be formed after the structure on the second principal surface 10b side is formed. Therefore, annealing at a high temperature may damage the structure already formed on the second principal surface 10b side. For example, an electrode containing Al may be melted.

However, according to the present embodiment, the buffer containing P (phosphorus) is distributed only near the first principal surface 10a, and annealing can be performed only near the first principal surface 10a by, for example, irradiation with a laser to carry out heating. Therefore, it is possible to eliminate the influence of heat on the second principal surface 10b side in the annealing step to form the fourth concentration peak 104. The buffer containing phosphorus (P) can be formed without impairing the structure on the second principal surface 10b side.

As compared with the case where the fourth concentration peak 104 is formed by protons, since the fourth concentration peak 104 is formed of P (phosphorus), there is no need to add a proton treatment step as compared with the first embodiment. Therefore, the efficiency of proton injection treatment can be improved as compared with the case where all concentration peaks are formed by proton injection.

### Third Embodiment

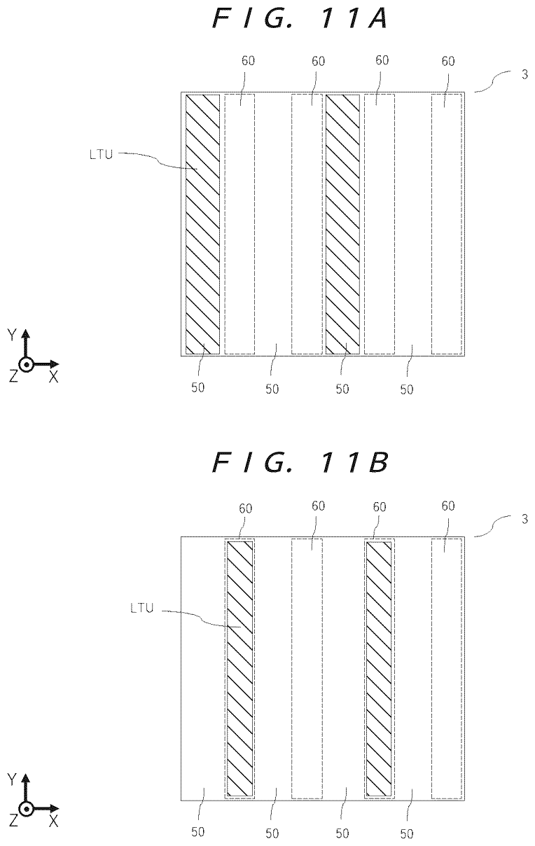

FIG. 11A is a top view of a semiconductor device 3 according to a third embodiment. A plurality of transistor regions 50 and a plurality of diode regions 60 are formed separately. Regions surrounded by dotted lines are the diode regions 60. FIG. 11A illustrates an example in which the transistor regions 50 and the diode regions 60 are arranged side by side in the X direction and extend in the Y direction.

First, the definition of a lifetime recovery region LTU will be described. The lifetime recovery region LTU is a region where a third concentration peak 103 is selectively formed in the XY plane. The lifetime recovery region LTU includes at least one impurity concentration peak between a second region R2 and a first principal surface 10a, and the carrier lifetime is recovered. For example, in the semiconductor device 1 according to the first embodiment, the transistor region 50 corresponds to the lifetime recovery region LTU as illustrated in FIG. 3A, compared to the carrier lifetime in the diode region 60 shown in FIG. 3B.

In the example illustrated in FIG. 11A, some transistor regions including the lifetime recovery regions LTU among the plurality of transistor regions 50 provided in the X direction are selectively provided. For example, the transistor regions 50 each of which includes the lifetime recovery region LTU are periodically arranged. FIG. 11A illustrates an example in which the diode regions 60 in two columns and the transistor region 50 in one column between the diode regions 60 in the two columns are formed between the lifetime recovery regions LTU adjacent to each other in the X direction.

According to the semiconductor device 3 of the present embodiment, the switching loss at turn-off can be reduced as compared with the case where the lifetime recovery region LTU is formed in all the transistor regions 50. The lifetime is not recovered in at least some of the transistor regions 50, and the removal of the carriers is promoted to improve the switching speed, resulting in the reduction of the removal. On the other hand, the oscillation amplitude can be reduced by the selectively provided lifetime recovery regions LTU.

The injection of holes from transistor regions 50 including no lifetime recovery region LTU to the adjacent diode region 60 is promoted. At the time of the recovery operation of the diode regions 60, the supply of holes from the transistor region 50 is promoted as the lifetime recovery region LTU is provided in the transistor region 50 with a small area. This is because the injection of holes from the transistor region 50 to the diode region 60 is interrupted by an increase in the concentration of donors in the third region R3 of the buffer region 100.

That is, as the lifetime recovery region LTU is formed with a smaller area, the oscillation of the voltage at the time of recovery of the diode region 60 can be minimized. Therefore, it is possible to further prevent the rapid removal of the carriers in the diode region 60 and to reduce the oscillation amplitude.

Furthermore, as the lifetime recovery region LTU is formed with a smaller area, the switching time is shortened, and the switching loss is reduced. According to the present embodiment, it is possible to improve the trade-off between the reduction of the oscillation amplitude and the reduction of the switching loss.

In addition, according to the present embodiment, the injection amount of impurities such as protons can be reduced. As compared to the case where the lifetime recovery regions LTU are formed in all the transistor regions 50, the injection amount of the impurities for recovering the carrier lifetime of the third region R3 can be reduced, and the injection efficiency can be improved.

As illustrated in FIG. 11A, according to the example in which the diode regions 60 in the two columns are formed between the lifetime recovery regions LTU adjacent to each other in the X direction, the injection amount of protons can be reduced to 50% as compared to the case where the lifetime recovery regions LTU are formed in all the transistor regions 50.

Note that, the present invention is not limited to the case where the lifetime recovery regions LTU are formed in the transistor regions 50, and as illustrated in FIG. 11B, some diode regions including the lifetime recovery regions LTU among the plurality of diode regions 60 provided in the X direction may be selectively provided in the XY plane. For example, the diode regions 60 each of which includes the lifetime recovery region LTU are periodically arranged. The transistor regions 50 in two columns and the diode region 60 in one column between the transistor regions 50 in two columns may be formed between the lifetime recovery regions LTU (formed in the diode regions 60) adjacent to each other in the X direction.

According to the example illustrated in FIG. 11B, it is possible to improve the trade-off between the reduction of the oscillation amplitude and the reduction of the switching loss. In addition, the injection amount of impurities such as protons can be reduced to improve the injection efficiency.

### Fourth Embodiment

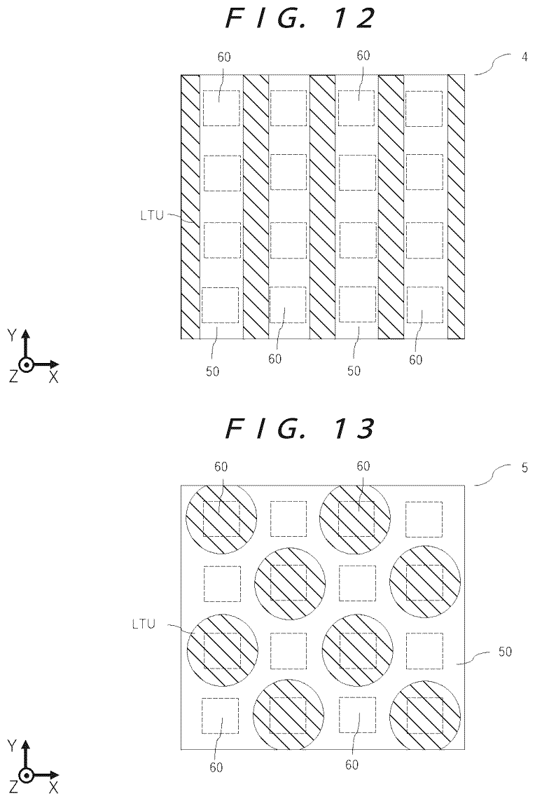

FIG. 12 is a top view of a semiconductor device 4 according to a fourth embodiment. Some redundant descriptions of the components common to the semiconductor device 3 according to the third embodiment will not be repeated.

In the present embodiment, diode regions 60 are formed in a dot shape spaced apart from each other in the X direction and the Y direction. Each of the diode regions 60 is formed within the dotted line illustrated in FIG. 12. Transistor regions 50 are arranged to extend in the X direction and the Y direction between the diode regions 60 in a lattice shape.

A plurality of lifetime recovery regions LTU is formed to extend in one direction (in FIG. 12, the Y direction is exemplified) in the lattice-shaped transistor regions 50. The plurality of lifetime recovery regions LTU is arranged in a direction intersecting the one direction (in FIG. 12, X direction).

According to the semiconductor device 4 of the present embodiment, the injection amount of the impurities can be reduced as compared to the case where the lifetime recovery region LTU is formed on the entire surface of the transistor region 50 with respect to the diode region 60 arranged in a dot shape.

In addition, since the lifetime recovery region LTU is not formed in the transistor region 50 adjacent to the diode region 60 in the Y direction, and the injection of holes from the transistor region 50 to the diode region 60 is promoted, it is possible to reduce the oscillation amplitude of the voltage by the slow removal of the carriers at the time of recovery of the diode region 60.

### Fifth Embodiment

FIG. 13 is a top view of a semiconductor device 5 according to a fifth embodiment. Some redundant descriptions of the components common to the semiconductor device 4 according to the fourth embodiment will not be repeated.

Lifetime recovery regions LTU are selectively formed in some of a plurality of diode regions 60 arranged in a dot shape. A plurality of the lifetime recovery regions LTU are formed to be spaced apart from each other in the X direction and the Y direction.

FIG. 13 illustrates an example in which one diode region 60 is formed between the lifetime recovery regions LTU adjacent to each other in the X direction and the Y direction. Two or three diode regions 60 may be formed between the adjacent lifetime recovery regions LTU.

In addition, each of the lifetime recovery regions LTU may be provided to protrude from each diode region 60 and reach a transistor region 50. In addition, the lifetime recovery regions LTU may not exist in the transistor region 50.

According to semiconductor device 5 of the present embodiment, it is possible to improve the trade-off between the reduction of the oscillation amplitude and the reduction of the switching loss.

In a region in which the lifetime recovery region LTU is formed in the diode regions 60, the carrier lifetime is recovered; thereby, the carrier recombination at the time of recovery of the diode region 60 can be slow down to reduce the oscillation amplitude of the voltage.

On the other hand, in the diode region 60 provided between the lifetime recovery regions LTU, the carrier lifetime is not recovered, and the switching speed is improved. As a result, the loss at the time of recovery can be reduced. Furthermore, the injection of holes from the transistor region 50 adjacent to the diode region 60 is promoted to cause the carrier recombination to be slow down. As a result, the oscillation amplitude of the voltage can be reduced.

Furthermore, in a part of the transistor region 50 in which the lifetime recovery regions LTU are not provided in the transistor region 50, the switching loss at turn-off can be reduced. In a case where the lifetime recovery regions LTU protrude into the transistor region 50 as in the example of FIG. 13, the lifetime is also recovered in the part of the transistor region 50, and the oscillation amplitude of the voltage waveform at the time of switching is minimized.

According to at least one embodiment described above, the buffer region 100 is provided between the drift region 11 and the first electrode 41 of the semiconductor substrate 10, and the third concentration peak 103 is selectively formed in the XY plane. As a result, the oscillation amplitude of the voltage waveform at the time of switching can be reduced. In addition, the third carrier lifetime LT3 is desirably 0.1 μs or greater and 10 μs or smaller.

The embodiments have been described above with reference to specific examples. However, the embodiments are not limited to these specific examples. That is, those obtained by appropriately changing the design of these specific examples by those skilled in the art are also included in the scope of the embodiments as long as they have the features of the embodiments. Each element included in each specific example described above and the arrangement, material, condition, shape, size, and the like thereof are not limited to those exemplified, and can be appropriately changed.

In addition, each element included in each of the above-described embodiments can be combined as far as technically possible, and combinations thereof are also included in the scope of the embodiments as long as they include the features of the embodiments. In addition, within the scope of the idea of the embodiments, a person skilled in the art can conceive various modification examples and amended examples, and it is understood that the modification examples and amended examples also belong to the scope of the embodiment.

Although some embodiments of the present invention have been described, these embodiments have been presented as examples, and are not intended to limit the scope of the invention. These novel embodiments can be implemented in various other forms, and various omissions, substitutions, and changes can be made without departing from the gist of the invention. These embodiments and modifications thereof are included in the scope and gist of the invention, and are included in the invention described in the claims and the equivalent scope thereof.

What is claimed is:

1. A semiconductor device comprising:
a semiconductor substrate that includes a first principal surface and a second principal surface, the first principal surface and the second principal surface facing each other in a first direction;
a drift region that is provided in the semiconductor substrate;
a buffer region that is provided between the first principal surface and the drift region and includes a plurality of concentration peaks in the first direction, having a higher impurity concentration than the drift region;
a first electrode that is provided on the first principal surface;
a second electrode that is provided on the second principal surface; and
a transistor region that includes a transistor provided with the first electrode serving as a collector electrode and the second electrode serving as an emitter electrode,
wherein the plurality of concentration peaks includes
a first concentration peak that is disposed closest to the second principal surface,
a second concentration peak that is disposed farther from the second principal surface than the first concentration peak and has a higher impurity concentration than an impurity concentration of the first concentration peak, and
a third concentration peak that is selectively provided in a plane intersecting the first direction between the first principal surface and the second concentration peak.

2. The semiconductor device according to claim 1,
wherein the impurity concentration of the second concentration peak is higher than an impurity concentration of the third concentration peak.

3. The semiconductor device according to claim 2,
further comprising a diode region that includes a diode provided with the first electrode serving as a cathode electrode and the second electrode serving as an anode electrode.

4. The semiconductor device according to claim 3,
wherein a number of the concentration peaks of the transistor region in the first direction is different from a number of the concentration peaks of the diode region in the first direction.

5. The semiconductor device according to claim 3,
wherein the third concentration peak is provided in the transistor region selectively among the transistor region and the diode region.

6. The semiconductor device according to claim 3,
wherein the third concentration peak is provided in the diode region selectively among the transistor region and the diode region.

7. The semiconductor device according to claim 1,
wherein the first concentration peak is formed at a depth of 10 μm or greater and 30 μm or smaller measured from the first principal surface.

8. The semiconductor device according to claim 1,
wherein the third concentration peak is formed at a depth of more than 0 μm and 10 μm or smaller measured from the first principal surface.

9. The semiconductor device according to claim 1,
wherein the third concentration peak has an impurity concentration of 1.0×10¹⁴ cm⁻³ or greater and 1.0×10¹⁷ cm⁻³ or smaller.

10. The semiconductor device according to claim 1,
wherein a carrier lifetime of a region including the third concentration peak in the buffer region is 0.001 μs or greater and 100 μs or smaller.

11. The semiconductor device according to claim 1,
further comprising a fourth concentration peak that is disposed closer to the first principal surface than the third concentration peak,
wherein an impurity concentration of the fourth concentration peak is higher than the impurity concentration of the third concentration peak.

12. The semiconductor device according to claim 11,
wherein an impurity that is used to form the first concentration peak, the second concentration peak, and the third concentration peak includes a proton, and
an impurity that is used to form the fourth concentration peak includes phosphorus.

13. The semiconductor device according to claim 3,
wherein the transistor region and the diode region form RC-IGBT.

14. The semiconductor device according to claim 3,
wherein a plurality of the transistor regions and a plurality of the diode regions are arranged in a second direction intersecting the first direction, and extend in a third direction intersecting the first direction and the second direction.

15. The semiconductor device according to claim 14,
wherein lifetime recovery regions each of which includes the third concentration peak are arranged in the second direction, extend in the third direction, and are selectively formed in a part of the transistor regions.

16. The semiconductor device according to claim 15,
wherein the diode regions are provided at least in two columns between the lifetime recovery regions adjacent to each other in the second direction.

17. The semiconductor device according to claim 3,
wherein diode regions, each of which is identical to the diode region, are provided in a dot shape while being spaced apart from each other in a second direction intersecting the first direction and in a third direction intersecting the first direction and the second direction, and
transistor regions, each of which is identical to the transistor region, is provided between the diode regions in a lattice shape, and
a plurality of lifetime recovery regions each of which includes the third concentration peak are arranged in the transistor region in the second direction and extend in the third direction.

18. A semiconductor device comprising:
a first electrode;
a semiconductor substrate including a RC-IGBT, provided on the first electrode;
a second electrode provided on the semiconductor substrate;
a buffer region provided in the semiconductor substrate including a plurality of concentration peaks; and
a cathode region with a first conductivity type and a collector region with a second conductivity type provided between the first electrode and the buffer region,
wherein the plurality of concentration peaks includes
a first concentration peak that is disposed closest to the first electrode, and
a second concentration peak that is disposed farther from the first electrode than the first concentration peak and has a higher impurity concentration than an impurity concentration of the first concentration peak,
wherein, in the buffer region, an impurity concentration of a region disposed farther from the first electrode than the second concentration peak being higher in a transistor region including the collector region than in a diode region including the cathode region.

19. A semiconductor device comprising:
a first electrode;
a semiconductor substrate including a RC-IGBT, provided on the first electrode;
a second electrode provided on the semiconductor substrate;
a buffer region provided in the semiconductor substrate including a plurality of concentration peaks; and
a cathode region with a first conductivity type and a collector region with a second conductivity type provided between the first electrode and the buffer region,
wherein the plurality of concentration peaks includes
a first concentration peak that is disposed closest to the first electrode, and
a second concentration peak that is disposed farther from the first electrode than the first concentration peak and has a higher impurity concentration than an impurity concentration of the first concentration peak,
wherein, in the buffer region, an impurity concentration of a region disposed farther from the first electrode than the second concentration peak being higher in a diode region including the cathode region than in a transistor region including the collector region.
